(19) United States
(12) Patent Application Publication
(10) Pub. No.: US 2026/0157062 A1
(43) Pub. Date: Jun. 4, 2026

(54) DISPLAY DEVICE

(71) Applicant: LG Display Co., Ltd., Seoul (KR)

(72) Inventor: Yoon Ho KWON, Paju-si (KR)

(73) Assignee: LG Display Co., Ltd., Seoul (KR)

(21) Appl. No.: 19/368,883

(22) Filed: Oct. 24, 2025

(30) Foreign Application Priority Data
Dec. 3, 2024 (KR) 10-2024-0177500

(51) Int. Cl. H10K 59/131; G06F 3/041; G06F 3/044; H10K 59/40

(52) U.S. Cl. CPC H10K 59/131; G06F 3/0412; H10K 59/40; G06F 3/0446

(57) ABSTRACT

The present specification discloses a display device including a display panel configured to display an image, touch electrodes provided on the display panel, and a planarization layer covering the touch electrodes. Dummy wires are provided on the planarization layer; and a polarizer provided on the dummy wires. The dummy wires contain a constituent element having a reduction potential lower than that of the constituent element forming the touch electrodes. By positioning these dummy wires between the polarizer and the touch electrodes, diffusion of reactive substances such as phosphorus or iodine from the polarizer toward the touch electrodes can be blocked. This structure reduces the risk of corrosion or short circuiting in the touch electrodes while maintaining optical performance. The configuration may be applied to various display types including organic light emitting diode displays, liquid crystal displays, micro light emitting diode displays, and mini light emitting diode displays.

### CROSS-REFERENCE TO RELATED APPLICATION

This application claims priority to and the benefit of Korean Patent Application No. 10-2024-0177500, filed Dec. 3, 2024, the specification of which is incorporated herein by reference in its entirety.

### BACKGROUND

### Technical Field

The present specification relates to a display device including a polarizer.

### Description of the Related Art

In an organic light-emitting diode OLED panel, external light such as sunlight or illumination may be reflected due to exposure of an electrode, and reduction in visibility and contrast ratio may be caused by reflected external light, resulting in deterioration of display quality.

For this reason, in the organic light-emitting diode panel, to block reflection of external light on a surface and to obtain black visibility in a state in which power supply is off, a circular polarizer in which a linear polarizer and a λ/4 retardation layer are combined may be attached to a viewing side of an OLED panel and used.

Recently, with a thickness reduction of a display device, a thickness reduction of a polarizer is also requested. There is a trend of removing a passivation layer that prevents corrosion of ITO in the OLED panel, according to the request for thickness reduction. Accordingly, there is a need to prevent the corrosion of the ITO by blocking the movement of iodine or phosphorus (P) from the polarizer to the panel.

### BRIEF SUMMARY

The present specification relates to a display device structure designed to prevent corrosion and short circuiting of touch electrodes caused by phosphorus (P) or iodine (I) diffusion from a polarizer. The display device includes dummy wires composed of metals having a lower reduction potential than aluminum (Al), such as magnesium (Mg), beryllium (Be), strontium (Sr), or barium (Ba). These metals preferentially react with diffusing phosphorus or iodine species before they can reach and damage the aluminum based touch electrodes. Chemical reaction pathways describing this protective mechanism are provided, ensuring electrode reliability even under moisture or elevated temperature conditions.

The dummy wires are positioned between the polarizer and the touch electrodes or within the polarizer itself, using honeycomb, stripe, matrix, triangular, or elliptical patterns to increase blocking efficiency while preserving optical transparency, display brightness, and touch sensing capability. Optional polymeric barrier layers with high curing rates, such as acrylate combined with urethane acrylate systems, may be included to further limit the diffusion of corrosive components and provide additional protection without impairing optical or electrical performance.

The structure ensures that the dummy wires do not overlap with light emitting elements, maintaining luminance and color quality, and can be applied to organic light emitting diode (OLED) displays, liquid crystal displays (LCD), micro light emitting diode (MicroLED) displays, and mini light emitting diode (MiniLED) displays. Through material selection, geometric arrangement, and chemical reaction mechanisms, the embodiments of the present specification provide a practical approach for next generation displays requiring improved reliability along with high optical quality.

For example, various embodiments of the present specification are directed to a display device capable of preventing short-circuiting of touch electrodes on a display panel by blocking movement of pollution components from a polarizer onto a display panel with dummy wires provided above the display panel.

The problems addressed by the embodiments of the present specification are not limited to those described above, and other problems not described will be clearly understood by those skilled in the art from the following description.

A display device according to an embodiment of the present specification includes a display panel that displays an image, touch electrodes provided on the display panel, a planarization layer that covers the touch electrodes, dummy wires provided on the planarization layer, and a polarizer provided on the dummy wires, in which the dummy wires include a constituent element having a reduction potential lower than a constituent element of the touch electrodes.

A display device according to another embodiment of the present specification includes a display panel that displays an image; touch electrodes provided on the display panels; a planarization layer that covers the touch electrode; and a polarizer that is provided on the planarization layer and includes dummy wires, in which the dummy wires include a constituent element with a reduction potential lower than a constituent element of the touch electrodes.

A display device according to another embodiment of the present specification comprising: a display panel that displays an image; a touch electrode provided on the display panel; a polarizer that is provided above the touch electrode; and a dummy wire provided between the polarizer and the touch electrode, wherein the dummy wire is provided between the touch electrode and the polarizer in a discontinuous manner so as to block a substance comprising iodine and/or phosphorus diffusing from the polarizer (in other words, a dummy wire provided between the polarizer and the touch electrode, wherein the dummy wire is arranged in a non-continuous pattern to block a substance containing iodine, phosphorus, or both from diffusing from the polarizer).

A display device according to another embodiment of the present specification comprising: a display panel that displays an image; a conductive pattern on the display panel; a polarizer located above the conductive pattern; and a dummy pattern disposed between the polarizer and the conductive pattern, wherein the dummy pattern comprises a material capable of blocking a substance diffusing from the polarizer. For instance, the conductive pattern may comprise one of a touch electrode, a sensing electrode, a driving electrode, a pixel electrode, or a common electrode.

Details according to various embodiments of the present specification in addition to the solutions of the above problems are included in the following description and the drawings.

According to the embodiments of the present specification, the dummy wires containing a constituent element with a reduction potential lower than a constituent element of the touch electrodes provided on the display panel is provided above the touch electrodes, so that a pollution component from the polarization element layer of the polarizer is prevented from flowing into the touch electrodes on the display panel. As a result, it is possible to prevent short-circuiting of the touch electrodes.

According to the embodiments of the present specification, the dummy wires containing Mg with a low reduction potential compared to Al in the touch electrodes on the display panel is positioned on a moisture permeation path of P in the polarization element layer of the polarizer to block bonding of P and Al, and when there is ionized Al, ionized Al is reduced near the dummy wires containing Mg. As a result, it is possible to prevent short-circuiting of the touch electrodes.

The effects of the present specification are not limited to the effects described above, and other effects not described will be understood by those skilled in the art to which the technical idea of the present specification belongs, from the following description.

### BRIEF DESCRIPTION OF THE SEVERAL VIEWS OF THE DRAWINGS

The above and other objects, features, and advantages of the present specification will become more apparent to those of ordinary skill in the art by describing exemplary embodiments thereof in detail with reference to the attached drawings, in which:

FIG. 1 is a diagram schematically illustrating a configuration of a display device to which a polarizer according to an embodiment of the present specification is applied;

FIG. 2 is a cross-sectional view schematically illustrating the display device including the polarizer according to the embodiment of the present specification;

FIG. 3 is a cross-sectional view illustrating the polarizer in the display device according to the embodiment of the present specification;

FIG. 4A is an enlarged cross-sectional view of an A portion in FIG. 3, and FIG. 4B is another alternative embodiment of FIG. 3;

FIG. 5 is a cross-sectional view illustrating a polarizer in a display device according to another embodiment of the present specification;

FIG. 6 is an enlarged cross-sectional view of a B portion in FIG. 5;

FIG. 7 is a plan view of a first example of dummy wires provided in the display device according to the embodiment of the present specification;

FIG. 8 is a plan view of a second example of dummy wires provided in the display device according to the embodiment of the present specification;

FIG. 9 is a plan view of a third example of dummy wires provided in the display device according to the embodiment of the present specification;

FIG. 10 is a plan view of a fourth example of dummy wires provided in the display device according to the embodiment of the present specification;

FIG. 11 is a plan view of a fifth example of dummy wires provided in the display device according to the embodiment of the present specification; and

FIG. 12 is a comparative embodiment of the present disclosure, showing a structure without dummy wiring.

### DETAILED DESCRIPTION

The advantages and features of the present specification, and methods of achieving them will be apparent from the embodiments described in detail below in conjunction with the accompanying drawings. However, the present specification is not limited to the following embodiments disclosed herein, but may be implemented in various different forms; rather, the present embodiments are provided to make the specification of the present specification complete and to enable those skilled in the art to fully comprehend the scope of the present specification.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Identical reference numerals may designate identical components throughout the description. Further, in describing the present specification, detailed descriptions of related known technologies may be omitted so as not to obscure the essence of the present specification. The terms such as “including,” “having,” and “consisting of” as used herein are generally intended to allow other components to be added unless the terms are used with the term “only.” References to components of a singular noun include the plural of that noun, unless specifically stated otherwise.

In the interpretation of components, they are construed to include margins of error, even if not explicitly stated.

When describing a positional relationship, for example, “on top of,” “above,” “below,” “next to,” or “adjacent to” describes the positional relationship of two parts, one or more other parts may be located between the two parts, unless “immediately,” “directly,” or “near to” is used.

When describing a temporal relationship, “after,” “subsequently to,” “following,” or, “before” describes a temporal antecedent or consequent relationship, which may not be continuous unless “immediately,” or “directly” is used.

The first, the second, and so on are used to describe various components, but these components are not limited by these terms. These terms are used only to distinguish one component from another. Therefore, the first component referred to below may be a second component within the technical spirit of the present specification.

Terms such as first, second, A, B, (a), or (b) may be used to describe elements of the embodiments of the present specification. Such terms are intended only to distinguish one component from another and are not intended to define the nature, sequence, order, or number of such components.

When a component is described as being “connected,” “coupled”, “accessed,” or “attached” to another component, it is to be understood that the component may be directly connected, coupled, accessed, or attached to the other component, but that there may also be other components interposed between the respective components which may be indirectly connected, coupled, accessed, or attached, unless specifically stated otherwise.

When a component is described as being “in contacted” or “overlapped” with another component, it is to be understood that the component may be in direct contacted or overlap with the other component, but that there may also be other components “interposed” between the respective components which may be indirect contacted or overlap with, unless specifically stated otherwise.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

It should be understood that the term “at least one” includes all possible combinations of one or more related components. For example, the meaning of “at least one of the first, second, and third components” may be understood to include not only the first, second, or third component, but also any combination of two or more of the first, second, and third components.

The terms “the first direction,” “the second direction,” “the third direction,” “the X-axis direction,” “the Y-axis direction,” and “the Z-axis direction” are not to be interpreted solely as a geometric relationship in which the relationship to one another is perpendicular, but may refer to a broader range of orientations in which the configurations of the present specification may function.

As used herein, a device may include a display device, such as a liquid crystal module (LCM) or an organic light-emitting display (OLED) module, which includes a display panel and a driver for driving the display panel. It may also include a set electronic apparatus or a set device, such as a laptop computer, a television set, a computer monitor, a vehicle or an automotive apparatus, or an equipment apparatus including another form of vehicle, and a mobile electronic apparatus, such as a smart phone or an electronic pad and the like, which is a complete product or finished product including LCMs, OLED modules, and the like.

Therefore, the device in the present specification may include a display device itself, such as an LCM module, OLED module, and the like, and a set device which is an application product or an end-consumer device including the LCM, OLED module, and the like.

Furthermore, in some embodiments, an LCM module and an OLED module composed of a display panel and a driver may be expressed as a display device, and an electronic device as a finished product including the LCM, OLED module (or panel) may be distinguished and expressed as a set device.

For example, the display device may include a liquid crystal display (LCD) panel or an organic light-emitting diode (OLED) display panel, and a source printed circuit board (PCB) which is a control part for driving the display panel. The set device may further include a set PCB, which is a set control part electrically connected to the source PCB to drive the entire set device.

The display panels used in the embodiments of the present specification may be any type of display panels such as a liquid crystal display panel, an organic light-emitting diode (OLED) display panel, and an electroluminescent display panel, but the embodiments are not limited thereto. For example, the display panel may be a display panel capable of generating sound by being vibrated by a vibration device according to the embodiments of the present specification. The display panel applied to the display device according to the embodiments of the present specification is not limited to the form or size of the display panel.

Each of the features of various embodiments of the present specification may be coupled or combined with one another in whole or in part, and may be technologically interlocked and operated in various ways, and each of the embodiments may be carried out independently or in conjunction with one another.

Hereinafter, various embodiments of the present specification will be described in detail with reference to the accompanying drawings. The scale of the components shown in the drawings has a different scale from the actual scale for convenience of explanation and is not limited to the scale shown in the drawings.

While various display devices such as an organic electroluminescence display, an electrophoresis display, a mini light-emitting diode (LED) display device, and a micro LED display device can be applied as a display device of the present specification, hereinafter, an organic electroluminescence display device will be described as an example for convenience of description.

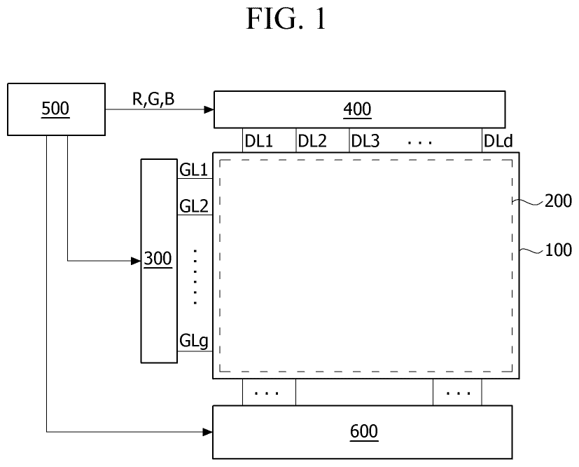

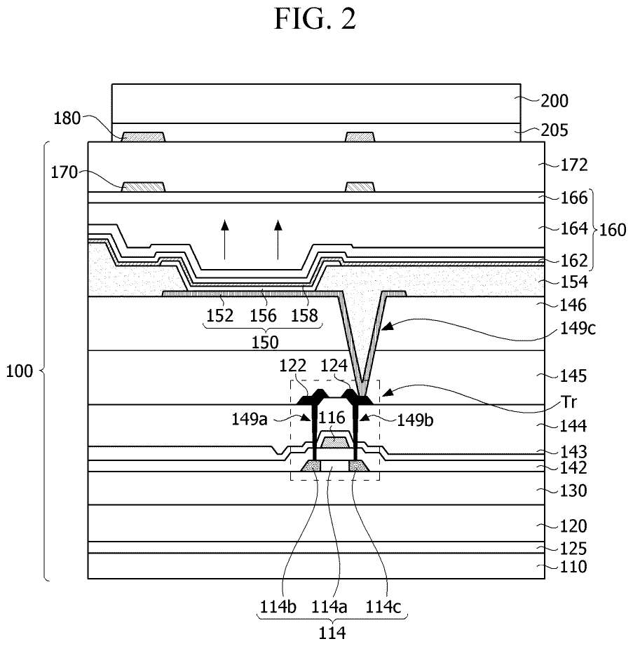

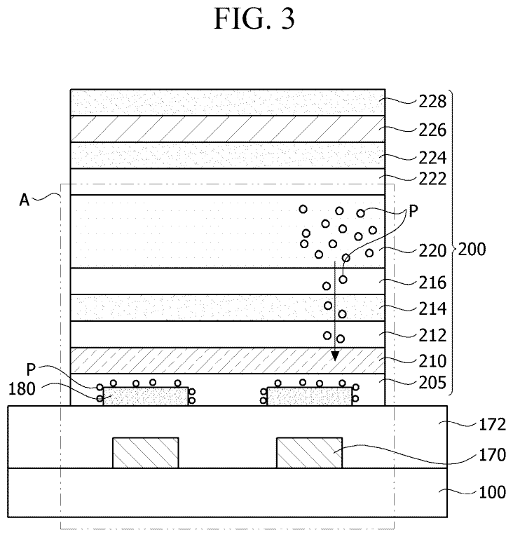

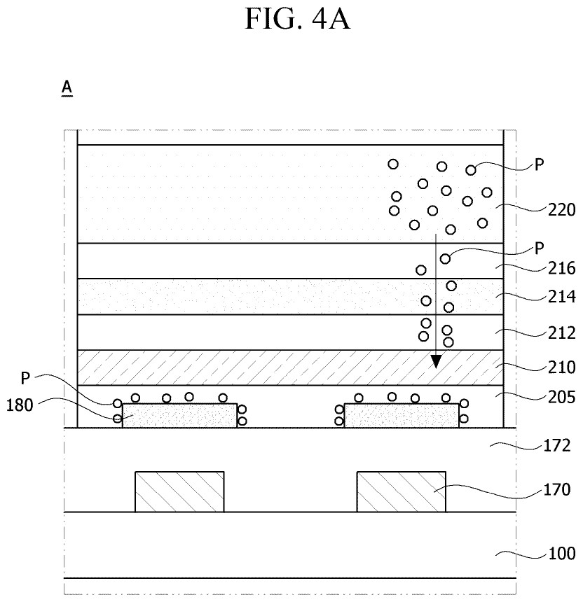

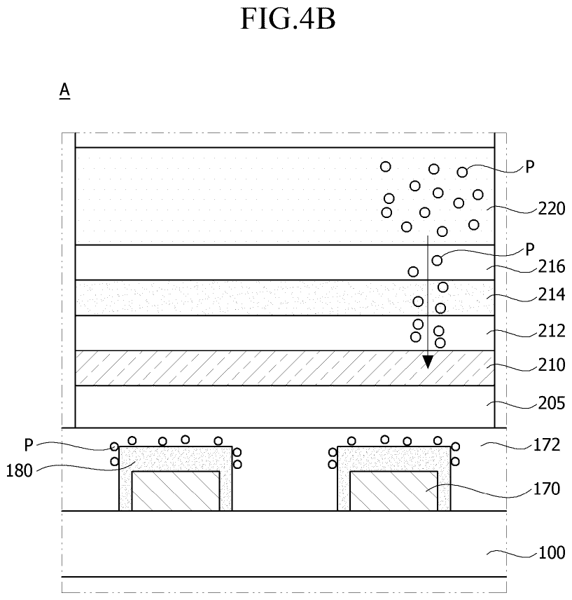

FIG. 1 is a diagram schematically illustrating a configuration of a display device to which a polarizer according to an embodiment of the present specification is applied. FIG. 2 is a cross-sectional view schematically illustrating the display device including the polarizer according to the embodiment of the present specification. FIG. 3 is a cross-sectional view illustrating the polarizer in the display device according to the embodiment of the present specification. FIG. 4A is an enlarged cross-sectional view of an A portion in FIG. 3, and FIG. 4B is another alternative embodiment of FIG. 3.

A display panel 100 substantially includes a plurality of sub-pixels, but in the drawing, only one sub-pixel may be illustrated for convenience of description.

Referring to FIGS. 1 and 2, the display device according to the present specification may include a display panel 100 in which pixels each having an organic light-emitting element 150 and a thin film transistor Tr that drives the organic light-emitting element 150 are provided, and a polarizer 200 provided on the display panel 100.

The display panel 100 may include panel drivers 300, 400, and 500 that sequentially supply a scan pulse to gate lines GL1 to GLg and supply a data voltage to data lines DL1 to DLd, and a touch sensor 600 that sequentially supplies a touch driving signal to touch electrodes 170 and determines a touch using touch sensing signals received from the touch electrodes 170.

In the display panel 100, sub-pixels may be provided for areas where a plurality of gate lines GL1 to GLg and data lines DL1 to DLd intersect each other. Each sub-pixel may include the organic light-emitting element 150 that outputs light, and a driver that drives the organic light-emitting element 150.

The organic light-emitting element 150 may include an anode electrode 152, a light emitting layer 156 (e.g., an organic light emitting layer), and a cathode electrode 158 provided on a substrate. Each sub-pixel may be divided by a bank layer 154, and the anode electrode 152 may cause light to be output with a current transmitted by the driving thin film transistor Tr.

The driver may include at least two thin film transistors Tr that are connected to the data lines DL1 to DLd and the gate lines GL1 to GLg to control the driving of the organic light-emitting element 150, and a storage capacitor. Here, at least two thin film transistors Tr may include a switching thin film transistor and a driving thin film transistor.

The anode electrode 152 of the organic light-emitting element 150 may be connected to a first power supply, and the cathode electrode 158 may be connected to a second power supply. The organic light-emitting element 150 may output light with predetermined luminance corresponding to a current supplied from the driving thin film transistor.

To this end, the driving thin film transistor may be connected between the first power supply and the organic light-emitting element 150, and the switching thin film transistor may be connected between the driving thin film transistor, and the data line DL and the gate line GL.

Referring to FIGS. 2 and 3, an inorganic insulating layer 125 may be provided on a first polyimide layer 110. The first polyimide layer 110 may be formed to have a uniform thickness by a spin coating method. The first polyimide layer 110 may be made of polyimide (PI) or a first insulating substrate is made of an organic insulating material including photo acryl. However, embodiments of the present specification are not limited thereto. The first polyimide layer 110 may be used as a first insulating substrate.

The inorganic insulating layer 125 may serve to prevent moisture from permeating into the display panel 100. An example of the material for the inorganic insulating layer 125 includes SiO₂. However, embodiments of the present specification are not limited thereto.

A second polyimide layer 120 may be formed on the inorganic insulating layer 125 to have a uniform thickness by a spin coating method. The second polyimide layer 120 may be made of polyimide (PI) or a second insulating substrate is made of an organic insulating material including photo acryl. However, embodiments of the present specification are not limited thereto. Also, the second polyimide layer 120 may be used as a second insulating substrate. The first polyimide layer 110 serving as the first insulating substrate and the second polyimide layer 120 serving as the second insulating substrate may configure a substrate having a stacked structure.

A buffer layer 130 may be formed above the second polyimide layer 120. The buffer layer 130 may be made of an inorganic insulating material or an organic insulating material. However, embodiments of the present specification are not limited thereto.

The thin film transistor Tr may be provided above the buffer layer 130. While various thin film transistors such as the switching thin film transistor, the driving thin film transistor, a sensing thin film transistor, and an auxiliary thin film transistor may be provided in each sub-pixel of the display panel 100, in the drawing, only one thin film transistor Tr is illustrated for convenience of description. Accordingly, the thin film transistor Tr may be the switching thin film transistor, the driving thin film transistor, the sensing thin film transistor, and the auxiliary thin film transistor.

For example, since the switching thin film transistor, the driving thin film transistor, the sensing thin film transistor, and the auxiliary thin film transistor may be configured as the same structure, the structures of all thin film transistors can be expressed by one thin film transistor Tr.

Referring to FIGS. 2 and 3, the thin film transistor Tr may include a semiconductor layer 114 disposed on the buffer layer 130, a gate electrode 116 disposed on a gate insulating layer 142 that covers the semiconductor layer 114 disposed on the buffer layer 130, and a source electrode 122 and a drain electrode 124 disposed on a planarization layer 144. Meanwhile, the planarization layer 144 may be disposed on a interlayer insulating layer 143 that covers the gate electrode 116 disposed on the gate insulating layer 142.

The buffer layer 130 may protect a thin film transistor that is formed in a subsequent step, from an impurity such as alkali ions or may block moisture or the like that may permeate from the outside. The buffer layer 130 may be a single layer made of silicon oxide (SiOx) or silicon nitride (SiNx) or may be a multi-layer thereof.

The semiconductor layer 114 may be made of an amorphous semiconductor such as amorphous silicon (a-Si), a crystalline semiconductor such as polycrystalline silicon (p-Si), or an oxide semiconductor such as indium gallium zinc oxide (IGZO). The semiconductor layer 114 may have a channel area 114a in a central area, and a source area 114b and a drain area 114c that are doped layers on both sides of the channel area 114a.

The gate electrode 116 may be composed as a single layer or a plurality of layers made of metal such as Cr, Mo, Ta, Cu, Ti, or an Al alloy. However, the material for the gate electrode 116 is not limited to such materials.

The interlayer insulating layer 143 may be composed as a single layer made of an organic material such as photo acryl or an inorganic material such as SiNx or SiOx, or a multi-layer thereof. The interlayer insulating layer 143 may be composed of a plurality of layers including an organic material layer and an inorganic material layer.

The source electrode 122 and the drain electrode 124 may be formed of a single layer or a plurality of layers made of metal such as Cr, Mo, Ta, Cu, Ti, Al, or an Al alloy. However, the materials for the source electrode 122 and the drain electrode 124 are not limited to such materials.

The source electrode 122 and the drain electrode 124 may be brought into ohmic contact with the source area 114b and the drain area 114c of the semiconductor layer 114 via a first contact hole 149a and a second contact hole 149b formed in the gate insulating layer 142, the interlayer insulating layer 143, and the planarization layer 144, respectively.

A bottom shield metal layer may be provided on the substrate below the semiconductor layer 114. The bottom shield metal layer minimizes a backchannel phenomenon caused by charges trapped in the substrate to prevent afterimages or deterioration of transistor performance. The bottom shield metal layer may be composed of a single layer or a plurality of layers made of Ti, Mo, or a Ti—Mo alloy, but is not limited thereto.

A first protection layer 145 and a second protection layer 146 having a third contact hole 149c to expose the source electrode 122 and the drain electrode 124 may be provided on the planarization layer 144. The first protection layer 145 and the second protection layer 146 may be formed of a single layer or a plurality of layers.

The first protection layer 145 and the second protection layer 146 may be formed of an organic material such as photo acryl, but is not limited thereto. For example, the first protection layer 145 and the second protection layer 146 may include an inorganic insulating layer or an organic insulating layer or the first protection layer 145 may be made of an inorganic insulating layer and the second protection layer 146 may be made of an organic insulating layer.

The anode electrode 152 that is electrically connected to the drain electrode 124 of the thin film transistor Tr via the third contact hole 149c may be formed on the second protection layer 146.

In some embodiments of the present disclosure, one or more barrier layers may be included in order to prevent species generated in the polarizer to emigrate to other layers, e.g., the touch electrodes or a conductive pattern. Such a barrier layer may have a high curing rate, e.g., 90% or higher, or 95% or higher. For example, the barrier layer includes an acrylic resin cured by including an acrylate-based monomer and a urethane acrylate oligomer. The acrylic resin cured by including an acrylate-based monomer and a urethane acrylate oligomer may have a higher curing rate than that of an acrylic resin which is cured without including the urethane acrylate oligomer. Therefore, the acrylic resin cured by including an acrylate-based monomer and a urethane acrylate oligomer has a high curing rate of 90% or higher to serve as a barrier layer.

The anode electrode 152 may be made of a single layer or a plurality of layers made of metal such as Ca, Ba, Mg, Al, or Ag, an alloy thereof. The anode electrode 152 may be connected to the drain electrode 124 of the thin film transistor Tr and an image signal may be applied to the anode electrode 152 from the outside.

The bank layer 154 may be formed at the boundary of each sub-pixel on the second protection layer 146. The bank layer 154 may be a kind of partition that defines the sub-pixel. The bank layer 154 may partition each sub-pixel to prevent light of specific colors output by adjacent pixels from being mixed and output.

The light emitting layer 156 may be formed on the anode electrode 152 and a partial area of an inclined surface of the bank layer 154. The light emitting layer 156 may be an R-light emitting layer that is formed in a red (R) pixel to emit red light, a G-light emitting layer that is formed in a green (G) pixel to emit green light, and a B-light emitting layer that is formed in a blue (B) pixel to emit blue light. The light emitting layer 156 may be a W-light emitting layer that emits white light. For example, the light emitting layer 156 may include an organic light emitting layer or an inorganic light emitting layer, for example, a nano-sized material layer, a quantum dot, a micro LED light emitting layer, or a mini LED light emitting layer, but is not limited thereto.

In the light emitting layer 156, in addition to an emission layer, an electron injection layer and a hole injection layer that inject electrons and holes into the light emitting layer, respectively, an electron transport layer and a hole transport layer that transport the injected electrons and holes to the emission layer, respectively, and the like may be formed.

In the light emitting layer 156, in addition to an emission layer, an electron injection layer and a hole injection layer that inject electrons and holes into the light emitting layer, respectively, an electron transport layer and a hole transport layer that transport the injected electrons and holes to the emission layer, respectively, and the like may be formed, but is not limited thereto.

The anode electrode 152, the light emitting layer 156, and the cathode electrode 158 may form the organic light-emitting element 150 to output light having a specific wavelength with application of a signal from the outside.

An encapsulation layer 160 may be formed on the cathode electrode 158. encapsulation layer 160 may be composed of a first encapsulation layer 162 made of an inorganic material, a second encapsulation layer 164 made of an organic material, and a third encapsulation layer 166 made of an inorganic material. In this case, the inorganic material may include SiNx and SiOx, but is not limited thereto. The organic material may include polyethylene terephthalate, polyethylene naphthalate, polycarbonate, polyimide, polyethylene sulfonate, polyoxymethylene, polyarylate, and a mixture thereof, but is not limited thereto.

Referring to FIGS. 2 and 3, a plurality of touch electrodes 170 may be provided on the third encapsulation layer 166 that composes the encapsulation layer 160, along a first direction and a second direction perpendicular to the first direction.

The plurality of touch electrodes 170 may be composed of a single layer or a plurality of layers made of metal such as Ca, Ba, Mg, Al, and Ag, or an alloy thereof. In the present specification, a case where the touch electrodes 170 are formed of a metal material including aluminum (Al) may be described as an example. However, embodiments of the present specification are not limited thereto.

The plurality of touch electrodes 170 may include first touch electrodes formed along the first direction and second touch electrodes formed along the second direction. An insulating material layer may be provided between the first touch electrodes and the second touch electrodes such that the first touch electrodes and the second touch electrodes are not electrically connected and are insulated from each other. In the present specification, the first touch electrodes and the second touch electrodes are collectively referred to as the touch electrodes 170.

In the display panel 100 on which the plurality of touch electrodes 170 are provided, a touch may be recognized using an amount of change in static capacitance formed between the first touch electrode and the second touch electrode.

When the first touch electrode formed in the first direction of the display panel 100 serves as a driving electrode, the second touch electrode formed in the second direction of the display panel 100 may serve as a reception electrode. When the first touch electrode serves as a reception electrode, the second touch electrode may serve as a driving electrode. That is, when the first touch electrode serves as a driving electrode, a touch driving signal for detecting a touch may be sequentially supplied to the first touch electrode.

In this case, when the user touches a specific area of the polarizer 200 attached on the display panel 100 in which the first touch electrode and the second touch electrode are provided, with a finger or a pen, a touch sensing signal may be received by the second touch electrode.

A touch and a touch position in the display panel 100 may be determined using the sensing signals received from the second touch electrodes. The function of supplying the touch driving signal and the function of determining a touch may be executed in the touch sensor 600.

A planarization layer 172 that covers the touch electrodes 170 may be provided on the third encapsulation layer 166.

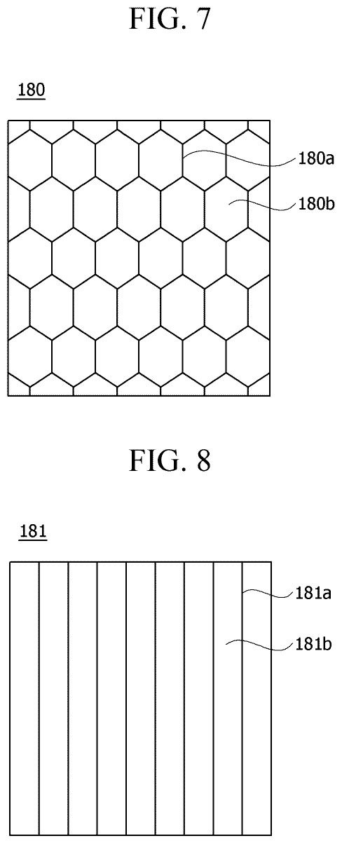

Dummy wires 180 may be provided on the planarization layer 172. The dummy wires 180 may be provided to overlap the touch electrodes 170 below the planarization layer 172. However, embodiments of the present specification are not limited thereto. For example, the dummy wires 180 may be provided partially not to overlap the touch electrodes 170 below the dummy wires 180. This is because the dummy wires 180 are made of a transparent metal material, and light emitted from the organic light-emitting element 150 may pass through the dummy wires 180 and may be output upward. However, the dummy wires 180 may be preferably provided to overlap the touch electrodes 170 below the dummy wires 180 in terms of luminance. The dummy wires 180 may be provided on the planarization layer 172 in the first direction and the second direction perpendicular to the first direction. The dummy wires 180 may be formed in a mesh type, a stripe type, or the like. Examples of the dummy wires will be described with reference to FIGS. 7 to 11 described below.

Specifically, the dummy wires 180 may be formed of a reactive and transparent metal material compared to aluminum (Al) for the touch electrodes 170. The reactive and transparent metal material may include magnesium (Mg). Here, the reactive and transparent metal compared to aluminum (Al) may include Be, Na, Ca, Sr, Ba, K, and Li in addition to magnesium (Mg). For example, as the material for the dummy wires 180, Mg, Be, Sr, Ba, or the like may be suitably used in view of stability, transparent electrode possibility, and the like.

The highly reactive metal compared to Al may mean metal having a low reduction potential compared to Al. The metal having a low reduction potential compared to Al may mean metal that easily reduces or ionizes other materials. Accordingly, as the material for the dummy wires 180, metal having a low reduction potential compared to Al applied to the touch electrode may be applied.

Referring to FIGS. 3 and 4A/4B, the polarizer 200 may be attached and provided on the display panel 100. The polarizer 200 may prevent reflection of light input from the outside to improve the visibility of the display device.

Specifically, the polarizer 200 may transmit only light in a specific polarization direction out of external light incident from the outside and may absorb remaining light, and light transmitted through the polarizer 200 may be reflected by the display panel 100 and may be incident on the polarizer 200 again. In this case, since the polarization direction of reflected external light is changed, light incident on the polarizer 200 again is absorbed by the polarizer 200 and is not output to the outside. As a result, it is possible to prevent reflection of external light.

The polarizer 200 may include a circular polarization film 210, a first protection film 214 provided on the circular polarization film 210, a polarization element layer 220 provided on the first protection film 214, a second protection film 224 provided on the polarization element layer 220, and a hard coating layer 226 provided on the second protection film 224.

As the polarizer 200, a circular polarizer may be used. When the circular polarizer is used, a λ/4 retardation film may be further provided between the polarizer 200 and the display panel 100.

A first adhesion layer 205 may be bonded between the display panel 100 and the circular polarization film 210 of the polarizer 200. A second adhesion layer 212 may be bonded between the circular polarization film 210 and the first protection film 214. A third adhesion layer 216 may be bonded between the first protection film 214 and the polarization element layer 220. A fourth adhesion layer 222 may be bonded between the polarization element layer 220 and the second protection film 224.

The first, second, third, and fourth adhesion layers 205, 212, 216, and 222 may be a clear adhesive layer. For example, the first, second, third, and fourth adhesion layers 205, 212, 216, and 222 may include a pressure-sensitive adhesive such as an optically clear adhesive (OCA) or optically clear resin (OCR).

As the first, second, third, and fourth adhesion layers 205, 212, 216, and 222, various pressure-sensitive adhesives or adhesives well known in the related art may be used, and the kinds are not particularly limited. Examples of the pressure-sensitive adhesives may include a rubber-based pressure-sensitive adhesive, an acrylic pressure-sensitive adhesive, a silicon-based pressure-sensitive adhesive, an urethane-based pressure-sensitive adhesive, a polyvinyl alcohol-based pressure-sensitive adhesive, a polyvinylpyrrolidone-based pressure-sensitive adhesive, a polyacrylamide-based pressure-sensitive adhesive, a cellulose-based pressure-sensitive adhesive, and a vinylalkyl ether-based pressure-sensitive adhesive.

An example of the adhesive may be a photo-curable adhesive, and the kind is not particularly limited.

The photo-curable adhesive is cross-linked and cured by receiving active energy rays such as ultraviolet (UV) or electron beam (EB) to provide strong adhesion, and may be made of a reactive oligomer, a reactive monomer, a photopolymerization initiator, or the like.

The reactive oligomer may be an important component that determines the property of an adhesive, and forms a cured layer by forming a polymer bond through a photopolymerization reaction. Examples of the available reactive oligomer may include polyester-based resin, polyether-based resin, polyurethane-based resin, epoxy-based resin, polyacrylic resin, and silicone-based resin.

The reactive monomer serves as a crosslinking agent and diluent for the above-described reactive oligomer and affects the adhesive property. Examples of the available reactive monomer may include a monofunctional monomer, a polyfunctional monomer, an epoxy-based monomer, vinyl ethers, and cyclic ethers.

The thickness of the first, second, third, and fourth adhesion layers 205, 212, 216, and 222 may be preferably 0.1 to 30 μm, and may be preferably applied as thin as possible within a range of not impairing properties such as processability and durability. More preferably, the thickness may be 1 to 25 μm. However, embodiments of the present specification are not limited thereto.

The circular polarization film 210 may serve to control reflected light through phase retardation. That is, the circular polarization film 210 may serve to prevent light incident on the display panel 100 from the outside from being reflected and emitted to the outside again.

The first protection film 214 and the second protection film 224 may serve to protect the polarization element layer 220.

The polarization element layer 220 may be formed of polyvinyl alcohol (PVA). However, embodiments of the present specification are not limited thereto.

The first protection film 214 and the second protection film 224 may be formed of photo isotropic tri-acetate cellulose (TAC) or acryl. However, embodiments of the present specification are not limited thereto.

The hard coating layer 226 may be formed of a material having properties such as scattering, hardness enhancement, anti-reflection, and low reflection.

To perform a polarization function, the polarization element layer 220, the first protection film 214 attached below the polarization element layer 220, the second protection film 224 attached above the polarization element layer 220, and the hard coating layer 226 attached to the surface of the second protection film 224 may compose a polarizing film.

The polarizing film may serve to change unpolarized light to linearly polarized light. That is, the polarizing film may perform the polarization function of transmitting only light that vibrates in one direction, out of incident light and absorbing light that vibrates in other directions.

A third protection film 228 that can be peeled off in terms of the visibility of the polarizing film may be stacked on the hard coating layer 226.

The peelable third protection film 228 may include a substrate and a pressures-sensitive adhesive layer formed on one surface of the substrate. The pressures-sensitive adhesive layer may be attached onto the hard coating layer 226 that is an uppermost layer of the polarizing film. The pressures-sensitive adhesive layer may be peeled off from the polarizing film when the polarizer 200 is attached to a cover window (not illustrated), and the third protection film 228 may be easily removed. The pressure-sensitive adhesive layer may be formed using the same material and forming method as the pressure-sensitive adhesive used in the first, second, third, and fourth adhesion layers 205, 212, 216, and 222.

Examples of the substrate of the third protection film 228 may include a polyester film such as polyethylene terephthalate, polybutylene terephthalate, polyethylene naphthalate, or a polyolefin film such as polypropylene or polyethylene.

In the present specification, after the third protection film 228 is peeled off, the hard coating layer 226 may be positioned as an outermost layer. The thickness of the third protection film 228 may be 10 to 150 μm, and preferably, may be 25 to 130 μm.

In some embodiments of the present disclosure, the polarizing elements or polarizing modules as used may contain components containing phosphorus element. For instance, when the polarizing element is positioned adjacent to a liquid crystal panel, there may be a risk of subjecting with high temperatures. In this case, it is necessary to add a phosphorus-containing flame retardant component, such as triphenyl phosphate (TPP), etc. For another example, in order to enhance the mechanical properties of the polarizing element, a phosphorus-containing crosslinking agent component may be added to the polarizing element. Consequently, in some cases, there is the problem of undesirable diffusion of phosphorus in the polarizing element or polarizing module.

Referring to FIG. 4A, the dummy wires 180 are provided on the touch electrodes 170 provided on the display panel 100, and a bonding relationship between constituent elements of the dummy wires 180 and the polarization element layer 220 in the polarizer 200 bonded to the display panel 100 will be examined through Chemical Formula 1 described below.

P+nH₂O→HₙP₄ⁿ⁻³Mg²⁺+HPO₄ⁿ⁻³→MgHPO₄ <Chemical Formula 1>

Moreover, in light emitting display devices, polarizing plates may assume polarization function by adsorbing iodine ions (such as I₃⁻ and I₅⁻). However, iodine element may cause electrode corrosion problems due to environmental factors such as moisture or high temperature. A bonding relationship between constituent elements of the dummy wires 180 and the polarization element layer 220 in the polarizer 200 bonded to the display panel 100 may be explained through Chemical Formula 2 and Chemical Formula 3 described below.

In the case of Chemical Formula 3, it can be understood that iodine ions react with oxygen or moisture, and the resulting iodinated hydrogen reacts with magnesium. Through Chemical Formulae 2 and 3, it can be explained that, regardless of whether the iodine element constituting the polarizing plate layer (220) is oxidized, the iodine element reacts with magnesium, which is a material of the dummy wiring (180), whereby corrosion of other electrodes can be prevented.

2I⁻→I₂+2e⁻3I₂+2Al→2Al³⁺+6I⁻I₂+Mg→Mg²⁺+2I⁻ <Chemical Formula 2>

I₂+H₂O→HIO+HI Mg+2HI→MgI₂+H₂ <Chemical Formula 3>

Referring to FIG. 4A and FIG. 4B, when the dummy wires 180 containing magnesium (Mg) are provided above the touch electrodes 170 on the display panel 100, as in Chemical Formula 1, Chemical Formula 2, and Chemical Formula 3, P or I components dissociated by moisture in the polarization element layer 220 of the polarizer 200 are reduced by reacting with magnesium (Mg) in the dummy wires 180 before reacting with aluminum (Al) in the touch electrodes 170 provided on the display panel 100. As a result, short-circuiting does not occur in other wires above the touch electrodes 170.

That is, Mg having a low standard reduction potential in the dummy wires 180 compared to Al in the touch electrodes 170 is positioned on a moisture permeation path in the polarization element layer 220 of the polarizer 200 to block bonding of Al and P, and when there is additional ionized Al, ionized Al is reduced near Mg, so that that short-circuiting cannot occur in other wires above the touch electrodes 170.

Specifically, as in FIG. 4A, the dummy wires 180 containing Mg are provided above the touch electrodes 170 provided on the display panel 100 to which the polarizer 200 is bonded, thereby blocking bonding of aluminum (Al) in the touch electrodes 170 and a specific component in the polarization element layer 220 of the polarizer 200, for example, phosphorus (P). As a result, it is possible to prevent corrosion that may be caused by bonding of Al in the touch electrodes170 and P in the polarization element layer 220.

As another alternative embodiment, referring to FIG. 4B, the dummy wires 180 may be provided on the touch electrodes 170 and surrounding the touch electrodes 170, thereby blocking the bonding of aluminum (Al) in the touch electrodes 170 and a specific component in the polarization element layer 220 of the polarizer 200, for example, phosphorus (P).

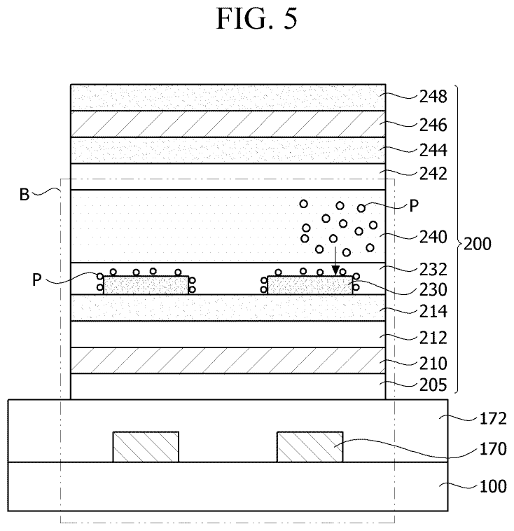

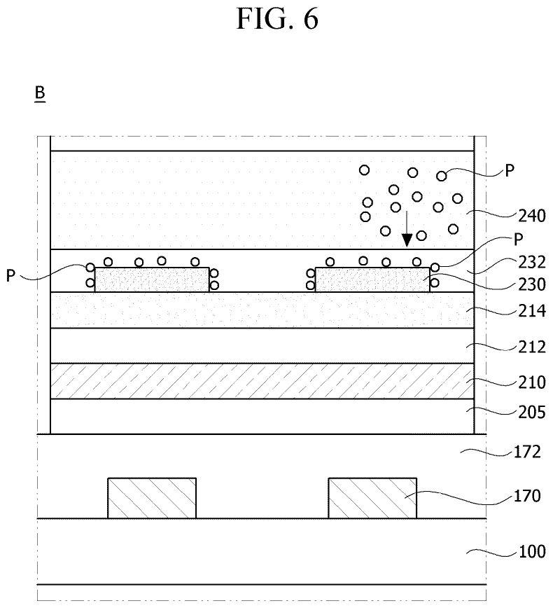

FIG. 5 is a cross-sectional view illustrating a polarizer in a display device according to another embodiment of the present specification. FIG. 6 is an enlarged cross-sectional view of a B portion in FIG. 5.

In the display device according to another embodiment of the present specification, the configurations of the display panel 100 and the polarizer 200 are the same as the configurations of FIGS. 3 and 4A and 4B, except for a configuration in which dummy wires 230 are provided in a polarizer 200, compared to the display device according to the embodiment of the present specification illustrated in FIGS. 3 and 4.

The display device according to another embodiment of the present specification will be described with reference to FIGS. 5 and 6 focusing on the polarizer 200 in which the dummy wires 230 are provided.

Referring to FIGS. 5 and 6, a plurality of touch electrodes 170 may be provided on the display panel 100 along the first direction and the second direction perpendicular to the first direction. The plurality of touch electrodes 170 may be composed of a single layer or a plurality of layers made of metal such as Ca, Ba, Mg, Al, and Ag, or an alloy thereof. In the present specification, a case where the touch electrodes 170 are formed of a metal material including aluminum (Al) will be described as an example. However, embodiments of the present specification are not limited thereto.

Specifically, the plurality of touch electrodes 170 may include first touch electrodes formed along the first direction and second touch electrodes formed along the second direction. An insulating material layer (not illustrated) may be provided between the first touch electrode and the second touch electrodes such that the first touch electrode and the second touch electrodes are not electrically connected and are insulated from each other. In the present specification, the first touch electrodes and the second touch electrodes are collectively referred to as the touch electrodes 170.

In the display panel 100 on which the plurality of touch electrodes 170 are provided, a touch may be recognized using an amount of change in static capacitance formed between the first touch electrode and the second touch electrode.

When the first touch electrode formed in the first direction of the display panel 100 serves as a driving electrode, the second touch electrode formed in the second direction of the display panel 100 may serve as a reception electrode. When the first touch electrode serves as a reception electrode, the second touch electrode may serve as a driving electrode. That is, when the first touch electrode serves as a driving electrode, a touch driving signal for detecting a touch may be sequentially supplied to the first touch electrode.

In this case, when the user touches a specific area of the polarizer 200 attached on the display panel 100 in which the first touch electrode and the second touch electrode are provided, with a finger or a pen, a touch sensing signal may be received by the second touch electrode.

A touch and a touch position in the display panel 100 may be determined using the sensing signals received from the second touch electrodes. The function of supplying the touch driving signal and the function of determining a touch may be executed in the touch sensor 600.

A planarization layer 172 that covers the touch electrodes 170 may be provided on the display panel 100.

The polarizer 200 may be bonded and provided on the planarization layer 172 on the display panel 100. The polarizer 200 can prevent reflection of light input from the outside to improve the visibility of the display device.

The polarizer 200 may transmit only light in a specific polarization direction out of external light incident from the outside and may absorb remaining light, and light transmitted through the polarizer 200 may be reflected by the display panel 100 and may be incident on the polarizer 200 again. In this case, since the polarization direction of reflected external light is changed, light incident on the polarizer 200 again is absorbed by the polarizer 200 and is not output to the outside. As a result, it is possible to prevent reflection of external light.

The polarizer 200 may include a circular polarization film 210, a first protection film 214 provided on the circular polarization film 210, dummy wires 230 provided on the first protection film 214, a polarization element layer 240 provided on the dummy wires 230, a second protection film 244 provided on the polarization element layer 240, and a hard coating layer 246 provided on the second protection film 244.

As the polarizer 200, a circular polarizer may be used. When the circular polarizer is used, a λ/4 retardation film may be further provided between the polarizer 200 and the display panel 100.

A first adhesion layer 205 may be bonded between the planarization layer 172 on the display panel 100 and the circular polarization film 210 of the polarizer 200. A second adhesion layer 212 may be bonded between the circular polarization film 210 and the first protection film 214. A third adhesion layer 232 may be bonded between the dummy wires 230 and the polarization element layer 240. A fourth adhesion layer 242 may be bonded between the polarization element layer 240 and the second protection film 244.

The first, second, third, and fourth adhesion layers 205, 212, 232, and 242 may be a clear adhesive layer. For example, the first, second, third, and fourth adhesion layers 205, 212, 232, and 242 may include a pressure-sensitive adhesive such as an optically clear adhesive (OCA) or optically clear resin (OCR).

As the first, second, third, and fourth adhesion layers 205, 212, 232, and 242, various pressure-sensitive adhesives or adhesives well known in the related art may be used, and the kinds are not particularly limited. Examples of the pressure-sensitive adhesives may include a rubber-based pressure-sensitive adhesive, an acrylic pressure-sensitive adhesive, a silicon-based pressure-sensitive adhesive, an urethane-based pressure-sensitive adhesive, a polyvinyl alcohol-based pressure-sensitive adhesive, a polyvinylpyrrolidone-based pressure-sensitive adhesive, a polyacrylamide-based pressure-sensitive adhesive, a cellulose-based pressure-sensitive adhesive, and a vinylalkyl ether-based pressure-sensitive adhesive.

An example of the adhesive may be a photo-curable adhesive, and the kind is not particularly limited.

The photo-curable adhesive is cross-linked and cured by receiving active energy rays such as ultraviolet (UV) or electron beam (EB) to provide strong adhesion, and may be made of a reactive oligomer, a reactive monomer, a photopolymerization initiator, or the like.

The reactive oligomer may be an important component that determines the property of an adhesive, and forms a cured layer by forming a polymer bond through a photopolymerization reaction. Examples of the available reactive oligomer may include polyester-based resin, polyether-based resin, polyurethane-based resin, epoxy-based resin, polyacrylic resin, and silicone-based resin.

The reactive monomer serves as a crosslinking agent and diluent for the above-described reactive oligomer and affects the adhesive property. Examples of the available reactive monomer may include a monofunctional monomer, a polyfunctional monomer, an epoxy-based monomer, vinyl ethers, and cyclic ethers.

The thickness of the first, second, third, and fourth adhesion layers 205, 212, 232, and 242 may be preferably 0.1 to 30 μm, and may be preferably applied as thin as possible within a range of not impairing properties such as processability and durability. More preferably, the thickness may be 1 to 25 μm. However, embodiments of the present specification are not limited thereto.

The circular polarization film 210 may serve to control reflected light through phase retardation. That is, the circular polarization film 210 may serve to prevent light incident on the display panel 100 from the outside from being reflected and emitted to the outside again.

The first protection film 214 and the second protection film 244 may serve to protect the polarization element layer 240.

The polarization element layer 240 may be formed of polyvinyl alcohol (PVA). However, embodiments of the present specification are not limited thereto.

The first protection film 214 and the second protection film 244 may be formed of photo isotropic tri-acetate cellulose (TAC) or acryl. However, embodiments of the present specification are not limited thereto.

The hard coating layer 246 may be formed of a material having properties such as scattering, hardness enhancement, anti-reflection, and low reflection.

To perform a polarization function, the polarization element layer 240, the second protection film 244 attached above the polarization element layer 240, and the hard coating layer 246 formed on the surface of the second protection film 244 may compose a polarizing film.

The polarizing film may serve to change unpolarized light to linearly polarized light. That is, the polarizing film may perform the polarization function of transmitting only light that vibrates in one direction, out of incident light and absorbing light that vibrates in other directions.

A third protection film 248 that can be peeled off in terms of the visibility of the polarizing film may be stacked on the hard coating layer 246.

The peelable third protection film 248 may include a substrate and a pressures-sensitive adhesive layer formed on one surface of the substrate. The pressures-sensitive adhesive layer may be attached onto the hard coating layer 246 that is an uppermost layer of the polarizing film. The pressures-sensitive adhesive layer may be peeled off from the polarizing film when the polarizer 200 is attached to a cover window (not illustrated), and the third protection film 248 may be easily removed. The pressure-sensitive adhesive layer may be formed using the same material and forming method as the pressure-sensitive adhesive used in the first, second, third, and fourth adhesion layers 205, 212, 232, and 242. However, embodiments of the present specification are not limited thereto.

Examples of the substrate of the third protection film 248 may include a polyester film such as polyethylene terephthalate, polybutylene terephthalate, polyethylene naphthalate, or a polyolefin film such as polypropylene or polyethylene.

In the present specification, after the third protection film 248 is peeled off, the hard coating layer 246 may be positioned as an outermost layer. The thickness of the third protection film 248 may be 10 to 150 μm, and preferably, may be 25 to 130 μm.

Referring to FIGS. 5 and 6, a chemical bonding relationship between constituent elements of the polarization element layer 240 and the dummy wires 230 in the polarizer 200 that is attached to the touch electrodes 170 provided on the display panel 100 will be examined through Chemical Formula 1 described above.

Specifically, the dummy wires 230 containing magnesium (Mg) may be provided below the polarization element layer 240 in the polarizer 200.

The dummy wires 230 may be formed of a reactive and transparent metal material compared to aluminum (Al) of the touch electrodes 170. The reactive and transparent metal material may include magnesium (Mg). Here, the reactive and transparent metal compared to aluminum (Al) may include Be, Na, Ca, Sr, Ba, K, and Li in addition to magnesium (Mg). Preferably, as the material for the dummy wires 230, Mg, Be, Sr, Ba, or the like may be suitably used in view of stability, transparent electrode possibility, and the like.

The highly reactive metal compared to Al may mean metal having a low reduction potential compared to Al. That is, the metal having a low reduction potential compared to Al may mean metal that easily reduces or ionizes other materials. Accordingly, as the material for the dummy wires 230, metal having a low reduction potential compared to Al applied to the touch electrode may be applied.

As in Chemical Formula 1, P or I components dissociated by moisture in the polarization element layer 240 of the polarizer 200 are reduced by reacting with magnesium (Mg) in the dummy wires 230 provided below the polarization element layer 240 before reacting with aluminum (Al) in the touch electrodes 170 provided on the display panel 100. As a result, short-circuiting does not occur in other wires above the touch electrodes 170.

That is, Mg having a low standard reduction potential in the dummy wires 230 below the polarization element layer 240 compared to Al in the touch electrodes 170 is positioned on a moisture permeation path in the polarization element layer 240 of the polarizer 200 to block bonding of Al and P, and when there is additional ionized Al, ionized Al is reduced near Mg, so that short-circuiting cannot occur in other wires above the touch electrodes 170.

Specifically, as in FIGS. 5 and 6, the dummy wires 230 containing magnesium (Mg) are provided below the polarization element layer 240 of the polarizer 200, thereby blocking bonding of aluminum (Al) in the touch electrodes 170 provided on the display panel 100 and a specific component in the polarization element layer 240 of the polarizer 200, for example, phosphorus (P). As a result, it is possible to prevent corrosion that may be caused by bonding of Al in the touch electrodes 170 and P in the polarization element layer 240.

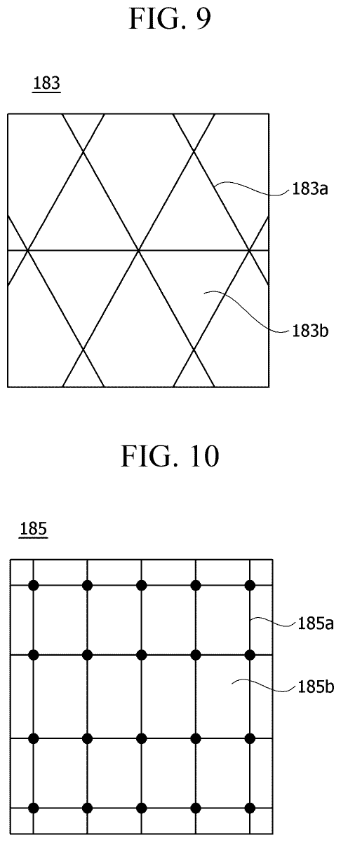

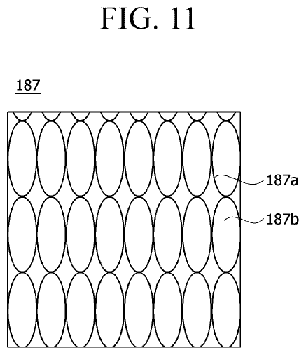

FIG. 7 is a plan view of a first example of dummy wires provided in the display device according to the embodiment of the present specification. FIG. 8 is a plan view of a second example of dummy wires provided in the display device according to the embodiment of the present specification. FIG. 9 is a plan view of a third example of dummy wires provided in the display device according to the embodiment of the present specification. FIG. 10 is a plan view of a fourth example of dummy wires provided in the display device according to the embodiment of the present specification. FIG. 11 is a plan view of a fifth example of dummy wires provided in the display device according to the embodiment of the present specification.

Specifically, FIG. 7 is a plan view illustrating a pattern form in a honeycomb shape as a first example of dummy wires 180 according to the present specification. Referring to FIG. 7, the dummy wires 180 according to the first example include mesh type transparent patterns 180a in a honeycomb shape and openings 180b formed between the transparent patterns 180a. A plurality of organic light-emitting elements 150 may be positioned below the plurality of openings 180b in an overlap manner. The transparent patterns 180a that divide the openings 180b may be positioned to overlap the touch electrodes 170 provided on the display panel 100 below the transparent patterns 180a. However, embodiments of the present specification are not limited thereto.

Accordingly, the dummy wires 180 in the honeycomb shape may be a most preferred form of the dummy wires taking into account optical properties, for example, luminance, color coordinates, moire, maximum contact of the polarizer with a pollution component, and the like. However, embodiments of the present specification are not limited thereto.

FIG. 8 is a plan view of a pattern form in a stripe shape as a second example of dummy wires 181 according to the present specification. Referring to FIG. 8, the dummy wires 181 according to the second example may have a structure in which a plurality of transparent patterns 181a having a linear shape in a longitudinal direction may be repeatedly provided on the planarization layer 172 at regular intervals in a transverse direction. For example, openings 181b may be formed between adjacent transparent patterns 181a. A plurality of organic light-emitting elements 150 may be positioned below the openings 181b in an overlap manner. The adjacent transparent patterns 181a may be positioned to overlap the touch electrodes 170 provided on the display panel 100 below the transparent patterns 181a. However, embodiments of the present specification are not limited thereto.

Accordingly, the second example of the dummy wires 181 in the stripe shape may be a preferred form of dummy wires taking into account optical properties, for example, luminance, color coordinates, moire, and maximum contact of the polarizer with a pollution component.

FIG. 9 is a plan view illustrating a transparent pattern form in a triangular shape as a third example of dummy wires 183 according to the present specification. Referring to FIG. 9, the dummy wires 183 according to the third example may have a structure in which a plurality of transparent patterns 183a having a triangular shape are repeatedly provided on the planarization layer (in FIG. 2, 172) in all directions. For example, a plurality of openings 183b may be formed between adjacent transparent patterns 183a in all directions. A plurality of organic light-emitting elements 150 may be positioned below the plurality of openings 183b in an overlap manner. The adjacent transparent patterns 183a may be positioned to overlap the touch electrodes 170 on the display panel 100 below the transparent patterns 183a. However, embodiments of the present specification are not limited thereto.

Accordingly, the third example of the mesh type dummy wires 183 in the triangular shape may be a suitable form of dummy wires taking into account optical properties, for example, luminance, color coordinates, moire, and maximum contact of the polarizer with a pollution component, and the like.

FIG. 10 is a plan view illustrating a pattern form in a matrix as a fourth example of dummy wires 185 according to the present specification. Referring to FIG. 10, the dummy wires 185 according to the fourth example may have a structure in which a plurality of transparent patterns 185a in a matrix are repeatedly provided. A plurality of openings 185b may be formed between adjacent transparent patterns 185a in a matrix. A plurality of organic light-emitting elements 150 may be positioned below the plurality of openings 185b in an overlap manner. The adjacent transparent patterns 185a may be positioned to overlap the touch electrodes 170 provided on the display panel 100 below the transparent patterns 185a. However, embodiments of the present specification are not limited thereto.

Accordingly, the fourth example of the dummy wires 185 in the matrix may also be a suitable form of dummy wires taking into account optical properties, for example, luminance, color coordinates, moire, and maximum contact of the polarizer with a pollution component, and the like.

FIG. 11 is a plan view illustrating a transparent pattern form in an elliptical shape as a fifth example of dummy wires 187 according to the present specification. Referring to FIG. 11, the dummy wires 187 according to the fifth example may have a structure in which the transparent patterns 187a having the elliptical shape are repeatedly provided in all directions. A plurality of openings 187b may be formed between the transparent patterns 187a repeatedly provided in all directions. A plurality of organic light-emitting elements 150 may be positioned below the plurality of openings 187b in an overlap manner. The adjacent transparent patterns 187a may be positioned to overlap the touch electrodes 170 provided on the display panel 100 below the transparent patterns 187a. However, embodiments of the present specification are not limited thereto.

Accordingly, the fifth example of the dummy wires 187 having the elliptical shape may also be a suitable form of dummy wires taking into account optical properties, for example, luminance, color coordinates, moire, and maximum contact of the polarizer with a pollution component, and the like.

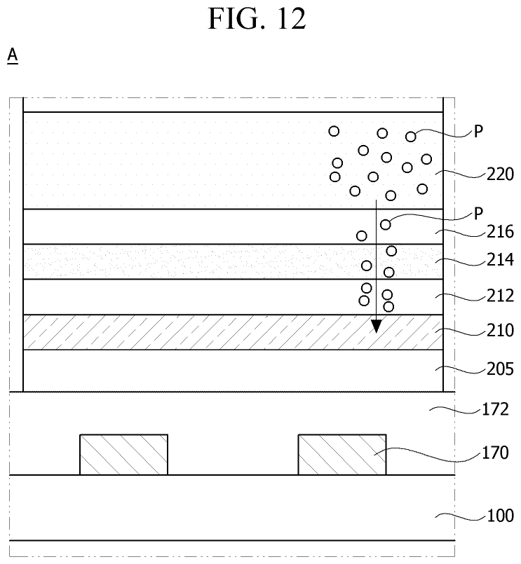

FIG. 12 shows a comparative embodiment relative to the embodiment of the present disclosure. In the comparative embodiment, the structure of the display device is similar to that of FIG. 4A and FIG. 4B, except that in the embodiment of FIG. 12, only a protective film (such as the first protection film 214) is provided without any dummy wirings. It was found that when only a protective film (such as an organic polymer film) is provided without any specific dummy wirings (such as the metal material described above), the absorption and blocking effects of the comparative embodiment for both iodine and phosphorus are significantly lower than those of the embodiment of the present disclosure. In a number of repeated tests, the absorption and blocking effects of comparative embodiment for each of iodine and phosphorus fall within a range of 10% to 30% lower than the embodiment of the present disclosure. Furthermore, the dummy wires in the embodiment do not overlap with the light-emitting elements in the light-emitting device, which can prevent any optical structure or protective film from adversely affecting the light-emitting efficiency of the display apparatus.

As described above, according to the embodiments of the present specification, the dummy wires containing a constituent element with a reduction potential lower than a constituent element of the touch electrodes provided on the display panel is provided above the touch electrodes, so that a pollution component from the polarization element layer of the polarizer is prevented from flowing into the touch electrodes on the display panel. As a result, it is possible to prevent short-circuiting of the touch electrodes.

According to the embodiments of the present specification, the Mg patterns having a low standard reduction potential compared to Al in the touch electrodes on the display panel are positioned on the moisture permeation path of P in the polarization element layer of the polarizer to block bonding of P and Al, and when there is ionized Al, ionized Al is reduced near the dummy wires containing Mg. As a result, it is possible to prevent short-circuiting of the touch electrodes.

Although the embodiments of the present specification have been described in more detail with reference to the accompanying drawings, the present specification is not necessarily limited to such embodiments, and may be variously modified within the scope thereof without departing from the technical spirit of the present specification.

Accordingly, the embodiments disclosed herein are provided for illustrative purposes and are not intended to limit the technical concept of the present specification, and the scope of the technical concept of the present specification is not limited to these embodiments.

Therefore, it should be understood that the embodiments described above are illustrative in all aspects and are not intended to be limiting.

The scope of protection of the present specification should be construed on the basis of the following claims, and all technical concepts within the equivalent scope thereof should be construed as falling within the scope of the present specification.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display panel configured to display an image;
touch electrodes provided on the display panel;
a planarization layer that covers the touch electrodes;
dummy wires provided on the planarization layer; and
a polarizer provided on the dummy wires,
wherein the dummy wires include a constituent element with a reduction potential lower than a constituent element of the touch electrodes.

2. The display device according to claim 1, wherein the dummy wires have a wire structure in a honeycomb shape.

3. The display device according to claim 1, wherein the display panel includes an organic light-emitting element.

4. The display device according to claim 3, wherein the organic light-emitting element includes:
a substrate,
a thin film transistor provided on the substrate, an anode electrode electrically connected to the thin film transistor, a light-emitting layer provided on the anode electrode, and a cathode electrode provided on the light-emitting layer.

5. The display device according to claim 1, wherein the dummy wires include Mg, Be, Sr, and Ba with a reduction potential lower than Al in the touch electrodes.

6. The display device according to claim 1, wherein the dummy wires include metal with a reduction potential lower than Al in the touch electrodes.

7. The display device according to claim 1, wherein the polarizer includes a circular polarization film, a plurality of protection films, a plurality of adhesion layers, a polarization element layer, and a hard coating layer.

8. The display device according to claim 7, wherein the plurality of protection films include a first protection film provided below the polarization element layer, a second protection film provided above the polarization element layer, and a third protection film provided on the hard coating layer.

9. The display device according to claim 7, wherein the plurality of protection films include a first protection film provided below the polarization element layer, and
wherein the plurality of adhesion layers include:
a first adhesion layer provided between the display panel and the circular polarization film positioned in a lowermost layer of the polarizer,
a second adhesion layer provided below the first protection film,
a third adhesion layer provided above the first protection film, and
a fourth adhesion layer provided above the polarization element layer.

10. The display device according to claim 8, wherein the polarization element layer includes polyvinyl alcohol, and the first protection film and the second protection film include photo isotropic tri-acetate cellulose or acryl.

11. The display device according to claim 3, wherein the dummy wires do not overlap with the organic light-emitting element.

12. A display device comprising:
a display panel configured to display an image;
touch electrodes provided on the display panel;
a planarization layer that covers the touch electrodes; and
a polarizer provided on the planarization layer, the polarizer including dummy wires,
wherein the dummy wires include a constituent element with a reduction potential lower than a constituent element of the touch electrodes.

13. The display device according to claim 12, wherein the dummy wires have a wire structure in a honeycomb shape.

14. The display device according to claim 12, wherein the display panel includes an organic light-emitting element.

15. The display device according to claim 14, wherein the organic light-emitting element includes:
a substrate,
a thin film transistor provided on the substrate,
an anode electrode electrically connected to the thin film transistor,
a light-emitting layer provided on the anode electrode, and
a cathode electrode provided on the light-emitting layer.

16. The display device according to claim 12, wherein the dummy wires include Mg, Be, Sr, and Ba with a reduction potential lower than Al in the touch electrodes.

17. The display device according to claim 12, wherein the dummy wires include metal with reactivity higher than Al in the touch electrodes.

18. The display device according to claim 12, wherein the polarizer includes a circular polarization film, a plurality of protection films, a plurality of adhesion layers, a polarization element layer, and a hard coating layer.

19. The display device according to claim 18, wherein the plurality of protection films include a first protection film provided below the dummy wires positioned below the polarization element layer, a second protection film provided above the polarization element layer, and a third protection film provided on the hard coating layer.

20. The display device according to claim 18, wherein the plurality of protection films include a first protection film provided below the polarization element layer, and
wherein the plurality of adhesion layers include:
a first adhesion layer provided between the display panel and the circular polarization film positioned in a lowermost layer of the polarizer,
a second adhesion layer provided below the first protection film,
a third adhesion layer provided above the dummy wires, and
a fourth adhesion layer provided above the polarization element layer.

21. The display device according to claim 19, wherein the polarization element layer includes polyvinyl alcohol, and the first protection film and the second protection film include photo isotropic tri-acetate cellulose or acryl.

22. The display device according to claim 14, wherein the dummy wires do not overlap with the organic light-emitting element.

23. A display device comprising:
a display panel configured to display an image;
a touch electrode provided on the display panel;
a polarizer provided above the touch electrode; and
a dummy wire provided between the polarizer and the touch electrode, wherein the dummy wire is arranged in a non-continuous pattern to block a substance containing iodine, phosphorus, or both from diffusing from the polarizer.

24. The display device according to claim 23, wherein the dummy wire overlaps with the touch electrode but does not overlap with a light emitting element of the display device in a cross-sectional view of the display device.

25. The display device according to claim 23, wherein the dummy wire is provided on the same layer as or on a different layer from the touch electrode, and the dummy wire covers and surrounds the touch electrode.

26. A display device comprising:
a display panel configured to display an image;
a conductive pattern provided on the display panel;
a polarizer provided above the conductive pattern; and
a dummy pattern provided between the polarizer and the conductive pattern, wherein the dummy pattern comprises a material configured to blocking a substance diffusing from the polarizer.

27. The display device according to claim 26, wherein the dummy pattern comprises a constituent element having a lower reduction potential than a constituent element of the conductive pattern.

28. The display device according to claim 26, wherein the conductive pattern comprises one of a touch electrode, a sensing electrode, a driving electrode, a pixel electrode, or a common electrode.

29. The display device according to claim 26, further comprising a barrier layer, the barrier layer including at least one of a first barrier layer between the polarizer and the dummy pattern, a second barrier layer between the dummy pattern and the conductive pattern, and a third barrier layer between the conductive pattern and the display panel.

30. The display device according to claim 26, wherein the barrier layer comprises a polymeric material with a curing rate of 90% or higher.

31. The display device according to claim 26, wherein the barrier layer comprises an acrylic resin cured by including an acrylate-based monomer and a urethane acrylate oligomer.
